(19) United States
(12) Patent Application Publication
(10) Pub. No.: US 2023/0088549 A1
(43) Pub. Date: Mar. 23, 2023

(54) QUANTUM DOT COMPOSITE, OPTICAL FILM, AND BACKLIGHT MODULE

(71) Applicant: NAN YA PLASTICS CORPORATION, Taipei (TW)

(72) Inventors: TE-CHAO LIAO, TAIPEI (TW); CHUN-CHE TSAO, TAIPEI (TW); Ren-Yu Liao, New Taipei City (TW)

(21) Appl. No.: 17/850,933

(22) Filed: Jun. 27, 2022

(30) Foreign Application Priority Data
Sep. 13, 2021 (TW) 110133986

(51) Int. Cl. H01L 33/50; C09K 11/08; C08L 33/08; C08L 33/10; C09K 11/06

(52) U.S. Cl. CPC H01L 33/502; C09K 11/0811; C08L 33/08; C08L 33/10; C09K 11/06; C08L 2203/20; C09K 2211/1408

(57) ABSTRACT

A quantum dot composite, an optical film, and a backlight module are provided. The quantum dot composite includes a polymerizable polymer and a plurality of quantum dot particles dispersed in the polymerizable polymer. Based on a total weight of the polymerizable polymer being 100 wt %, the polymerizable polymer includes: 5 wt % to 30 wt % of a monofunctional acrylic monomer, 10 wt % to 40 wt % of a multifunctional acrylic monomer, 15 wt % to 40 wt % of a thiol compound, 1 wt % to 5 wt % of a photoinitiator, 5 wt % to 25 wt % of an allyl monomer, and 3 wt % to 30 wt % of scattering particles.

### CROSS-REFERENCE TO RELATED PATENT APPLICATION

This application claims the benefit of priority to Taiwan Patent Application No. 110133986, filed on Sep. 13, 2021. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a quantum dot composite, an optical film, and a backlight module, and more particularly to a quantum dot composite, an optical film, and a backlight module that are without a barrier layer.

### BACKGROUND OF THE DISCLOSURE

In response to increasing requirements for the color quality of displays, developing displays that have high color saturation and low thickness has become the mainstream trend. Compared with an organic light-emitting diode (OLED), quantum dots have a higher luminous efficiency, a wider color gamut, and a higher color purity. Therefore, researchers in the relevant field are dedicated to manufacturing optical films from quantum dot materials and using the optical films as backlight sources of the displays, so as to provide a better viewing experience for viewers.

However, the quantum dot materials have a low resistance to moisture and oxygen. Once the optical films containing the quantum dot materials are in contact with moisture or oxygen, the quantum dot materials are likely to be deteriorated, and the luminous efficiency of the quantum dot materials can be negatively influenced. In order to prevent the quantum dot materials from being negatively influenced by moisture and oxygen, a barrier layer is disposed on the optical film that is currently available on the market, so that stability of the displays can be enhanced and a service life thereof can be prolonged.

For example, in certain conventional optical films n1 (as shown in FIG. 5), barrier layers B are disposed between a quantum dot layer 1′ and a first substrate layer 2 and between the quantum dot layer 1′ and a second substrate layer 3, so as to prevent external moisture and oxygen from contacting the quantum dot layer 1′. In other conventional optical films n1 (as shown in FIG. 6), the barrier layers B are disposed on the first substrate layer 2 and the second substrate layer 3. In other words, the barrier layers B are disposed on outermost sides of the conventional optical films n1, such that moisture and oxygen can be obstructed.

The barrier layer can enhance a barrier effect of the optical film against moisture and oxygen. However, a total cost and the difficulty of manufacturing the optical film can be increased by involving barrier layers, especially those with high barrier effect. Further, an overall thickness of a product cannot be easily reduced. Based on reasons mentioned above, the display that uses the quantum dot film still has a high price and is difficult to be popularized. Therefore, how to enhance the barrier effect of the quantum dot film against moisture and oxygen by adjusting a composition of the quantum dot film, so as to overcome the above-mentioned inadequacies, has become an important issue in the industry.

### SUMMARY OF THE DISCLOSURE

In response to the above-referenced technical inadequacies, the present disclosure provides a quantum dot composite, an optical film, and a backlight module.

In one aspect, the present disclosure provides a quantum dot composite. The quantum dot composite includes a polymerizable polymer and a plurality of quantum dot particles dispersed in the polymerizable polymer. Based on a total weight of the polymerizable polymer being 100 wt %, the polymerizable polymer includes: 5 wt % to 30 wt % of a monofunctional acrylic monomer, 10 wt % to 40 wt % of a multifunctional acrylic monomer, 15 wt % to 40 wt % of a thiol compound, 1 wt % to 5 wt % of a photoinitiator, 5 wt % to 25 wt % of an allyl monomer, and 3 wt % to 30 wt % of scattering particles.

In certain embodiments, a concentration of the quantum dot particles in the quantum dot composite ranges from 0.1 wt % to 5 wt %.

In certain embodiments, a weight amount of the thiol compound is 15 times to 50 times a weight amount of the quantum dot particles.

In certain embodiments, a ligand is formed on surfaces of the quantum dot particles, and the ligand is selected from the group consisting of: oleic acid, alkyl phosphine, alkyl phosphine oxide, alkyl amines, alkyl carboxylic acid, alkyl mercaptan, and alkyl phosphonic acid.

In certain embodiments, the thiol compound is selected from the group consisting of: 2, 2′-(ethylenedioxy)diethyl mercaptan, 2, 2′-thiodiethyl mercaptan, trimethylolpropane tris(3-mercaptopropionate), polyethylene glycol dithiol, pentaerythritol tetrakis(3-mercaptopropionate), ethylene glycol dimercaptoacetate, ethyl 2-mercaptopropionate, pentaerythritol tetrakis(3-mercaptobutyrate), 1, 3, 5-tris(3-mercapto butyloxyethyl)-1, 3, 5-triazine-2, 4, 6(1H, 3H, 5H)-trione, and 1,4-butanediol bis(3-mercaptobutyric acid) ester. In certain embodiments, the thiol compound includes a primary mercaptan and a secondary mercaptan, and a weight ratio of the primary mercaptan to the secondary mercaptan ranges from 1:3 to 3:1.

In certain embodiments, the monofunctional acrylic monomer is selected from the group consisting of: dicyclopentadiene methacrylate, triethylene glycol ethyl ether methacrylate, alkoxylated lauryl acrylate, isobornyl methacrylate, lauryl methacrylate, stearyl methacrylate, lauryl acrylate, isobornyl acrylate, tridecyl acrylate, caprolactone acrylate, octylphenol acrylate, and alkoxylated acrylate.

In certain embodiments, the multifunctional acrylic monomer is selected from the group consisting of: trimethylolpropane triacrylate, ethoxylated trimethylolpropane triacrylate, ditrimethylolpropane tetraacrylate, pentaerythritol tetraacrylate, dipentaerythritol pentaacrylate, and ethoxylated pentaerythritol tetraacrylate.

In certain embodiments, the allyl monomer is selected from the group consisting of: diallyl terephthalate, diallyl phthalate, diallyl carbonate, diallyl oxalate, and diallyl isophthalate.

In another aspect, the present disclosure provides an optical film. The optical film includes a quantum dot layer, a first substrate layer, and a second substrate layer. The quantum dot layer is disposed between the first substrate layer and the second substrate layer. The quantum dot layer is formed by solidification of a quantum dot composite. The quantum dot composite includes a polymerizable polymer and a plurality of quantum dot particles dispersed in the polymerizable polymer. Based on a total weight of the polymerizable polymer being 100 wt %, the polymerizable polymer includes: 5 wt % to 30 wt % of a monofunctional acrylic monomer, 10 wt % to 40 wt % of a multifunctional acrylic monomer, 15 wt % to 40 wt % of a thiol compound, 1 wt % to 5 wt % of a photoinitiator, 5 wt % to 25 wt % of an allyl monomer, and 3 wt % to 30 wt % of scattering particles.

In certain embodiments, materials of the first substrate layer and the second substrate layer are polyethylene terephthalate, and a thickness of each of the substrate layer and the second substrate layer ranges from 20 μm to 120 μm. In certain embodiments, a thickness of the quantum dot layer ranges from 30 μm to 130 μm.

In certain embodiments, the optical film is without a barrier layer.

In yet another aspect, the present disclosure provides a backlight module. The backlight module includes a light guide unit, at least one light emitting unit, and an optical film. The light guide unit has a light entering side and a light emitting side. The at least one light emitting unit generates a light that is projected to the light entering side. The optical film is disposed on the light entering side of the light guide unit and disposed between the light guide unit and the at least one light emitting unit. The optical film includes: a quantum dot layer, a first substrate layer, and a second substrate layer. The quantum dot layer is disposed between the first substrate layer and the second substrate layer. The quantum dot layer is formed by solidification of a quantum dot composite. The quantum dot composite includes a polymerizable polymer and a plurality of quantum dot particles dispersed in the polymerizable polymer. Based on a total weight of the polymerizable polymer being 100 wt %, the polymerizable polymer includes: 5 wt % to 30 wt % of a monofunctional acrylic monomer, 10 wt % to 40 wt % of a multifunctional acrylic monomer, 15 wt % to 40 wt % of a thiol compound, 1 wt % to 5 wt % of a photoinitiator, 5 wt % to 25 wt % of an allyl monomer, and 3 wt % to 30 wt % of scattering particles.

Therefore, in the quantum dot composite, the optical film, and the backlight module provided by the present disclosure, by virtue of “5 wt % to 30 wt % of a monofunctional acrylic monomer”, “10 wt % to 40 wt % of a multifunctional acrylic monomer”, “15 wt % to 40 wt % of a thiol compound”, “1 wt % to 5 wt % of a photoinitiator”, “5 wt % to 25 wt % of an allyl monomer”, and “3 wt % to 30 wt % of scattering particles,” barrier effects of the quantum dot composite, the optical film, and the backlight module against moisture and oxygen can be enhanced.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a partial cross-sectional side view of a quantum dot composite according to one embodiment of the present disclosure;

FIG. 2 is a partial cross-sectional side view of an optical film according to one embodiment of the present disclosure;

FIG. 3 is a partial cross-sectional side view of the optical film according to another embodiment of the present disclosure;

FIG. 4 is a schematic side view of a backlight module according to the present disclosure;

FIG. 5 is a cross-sectional side view of a conventional optical film; and

FIG. 6 is a cross-sectional side view of another conventional optical film.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

The present disclosure provides a quantum dot composite that has a good barrier effect against moisture and oxygen, so as to prevent quantum dots from deterioration caused by contacting moisture and oxygen. Therefore, when the quantum dot composite is used to form an optical film, a quantum dot layer formed by solidification of the quantum dot composite can also have a good barrier effect against moisture and oxygen. Accordingly, a barrier layer can be absent from the optical film of the present disclosure, but the quantum dots can still be protected.

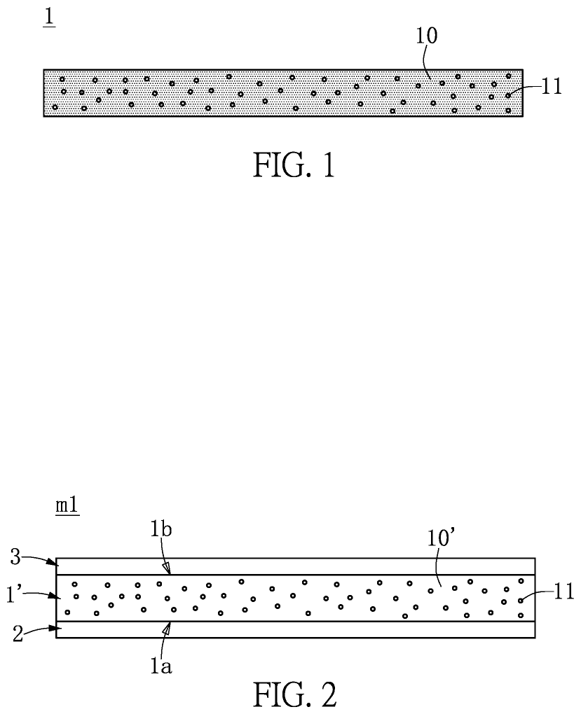

Referring to FIG. 1, a quantum dot composite 1 is provided in the present disclosure. The quantum dot composite 1 includes a polymerizable polymer 10 and a plurality of quantum dot particles 11 dispersed in the polymerizable polymer 10. The quantum dot composite 1 has a good barrier effect against moisture and oxygen.

A concentration of the quantum dot particles 11 in the polymerizable polymer 1 ranges from 0.1 wt % to 5 wt %. In certain embodiments, the concentration of the quantum dot particles 11 in the polymerizable polymer 1 ranges from 0.2 wt % to 4 wt %. Preferably, the concentration of the quantum dot particles 11 in the polymerizable polymer 1 ranges from 0.3 wt % to 3 wt %.

The quantum dot particles 11 can include red quantum dots, green quantum dots, blue quantum dots, or any combination thereof In addition, the quantum dot particles 11 can be quantum dots that have a monolayer structure or a core-sheath structure. The possible types of the quantum dot particles 11 mentioned below are for illustration purposes only, and the present disclosure is not limited thereto.

When the quantum dot particles 11 have the core-sheath structure, the quantum dot particles 11 include a core and a sheath that encapsulates the core. A material of the core and a material of the sheath can be a composite containing elements in Group II-VI, Group II-V, Group III-VI, Group III-V, Group IV-VI, Group II-IV-VI, or Group II-IV-V. The term “Group” refers to the group in the periodic table.

For example, the materials of the core and the sheath of the quantum dot particles 11 can include CdSe/ZnS, InP/ZnS, PdSe/PbS, CdSe/CdS, CdTe/CdS, or CdTe/ZnS.

In some embodiments, a ligand is formed on surfaces of the quantum dot particles 11, so as to maintain stability of the quantum dot particles 11. Specifically, the ligand is selected from the group consisting of: oleic acid, alkyl phosphine, alkyl phosphine oxide, alkyl amines, alkyl carboxylic acid, alkyl mercaptan, and alkyl phosphonic acid. However, the present disclosure is not limited thereto.

A compactness of the polymerizable polymer 10 (after solidification) can be enhanced by improving a composition and a ratio of the polymerizable polymer 10. Accordingly, the polymerizable polymer 10 (after solidification) can have a good barrier effect against moisture and oxygen, and physical properties of the polymerizable polymer 10 (after solidification) can be maintained.

Specifically, based on a total weight of the polymerizable polymer 10 being 100 wt %, the polymerizable polymer 10 includes 5 wt % to 30 wt % of a monofunctional acrylic monomer, 10 wt % to 40 wt % of a multifunctional acrylic monomer, 15 wt % to 40 wt % of a thiol compound, 1 wt % to 5 wt % of a photoinitiator, 5 wt % to 25 wt % of an allyl monomer, and 3 wt % to 30 wt % of scattering particles.

The monofunctional acrylic monomer and the multifunctional acrylic monomer are both molecules that contain a functional group. The monofunctional acrylic monomer is a molecule that has one functional group which is able to participate in polymerization. The multifunctional acrylic monomer is a molecule that has more than one functional group which is able to participate in polymerization.

Compared to the multifunctional acrylic monomer, an addition of the monofunctional acrylic monomer enables the quantum dot composite 1 to have properties of a low solidification rate, a low crosslink density, and a low viscosity. Therefore, the higher a weight ratio of the monofunctional acrylic monomer in the polymerizable polymer 10 is, the lower a volume shrinkage rate and the crosslink density of the quantum dot composite 1 are. However, a dispersity of the quantum dot particles 11 in the polymerizable polymer 10 can be increased by the addition of the monofunctional acrylic monomer.

Comparatively speaking, an addition of the multifunctional acrylic monomer enables the quantum dot composite 1 to have properties of a high solidification rate and a high viscosity. When a weight ratio of the multifunctional acrylic monomer is high, the crosslink density of the quantum dot composite 1 (after solidification) can be enhanced, but the volume shrinkage rate and a hardness of the quantum dot composite 1 are also increased. In addition, the addition of the multifunctional acrylic monomer increases the viscosity of the quantum dot composite 1. When the weight ratio of the multifunctional acrylic monomer is too high, the dispersity of the quantum dot particles 11 in the polymerizable polymer 10 is decreased.

It should be noted that when the dispersity of the quantum dot particles 11 in the polymerizable polymer 10 is poor, a wavelength of an excitation light generated by the excited quantum dot particles 11 will have a wide full width at half maximum (FWHM), a light conversion efficiency of the quantum dot particles 11 will be poor, and a brightness of the quantum dot particles 11 will be low, thereby not satisfying practical application requirements.

Therefore, in the embodiments of the present disclosure, the quantum dot composite 1 (after solidification) needs to have a high compactness, but the dispersity of the quantum dot particles 11 in the polymerizable polymer 10 also needs to be taken into consideration. Further, the volume shrinkage rate, the hardness, and a brittleness of the quantum dot composite 1 are to be prevented from being too high.

Based on the above descriptions, the addition of the monofunctional acrylic monomer can increase the dispersity of the quantum dot particles 11 in the polmerizable polymer 10. However, when an amount of the monofunctional acrylic monomer is too high, the compactness of the quantum dot composite 1 (after solidification) will be decreased. Accordingly, the barrier effect against moisture and oxygen and the solidification rate of the quantum dot composite 1 (after solidification) will be decreased. Therefore, a weight ratio of the monofunctional acrylic monomer to the multifunctional acrylic monomer ranges from 0.15 to 0.75.

Preferably, the weight ratio of the monofunctional acrylic monomer to the multifunctional acrylic monomer ranges from 0.2 to 0.62. More preferably, the weight ratio of the monofunctional acrylic monomer to the multifunctional acrylic monomer ranges from 0.25 to 0.55. Therefore, the dispersity of the quantum dot particles 11 in the polmerizable polymer 10 and the barrier effect of the polmerizable polymer 10 (after solidification) against moisture and oxygen can be enhanced.

In some embodiments, the weight amount of the monofunctional acrylic monomer in the polmerizable polymer 10 ranges from 7.5 wt % to 25 wt %. Preferably, the weight amount of the monofunctional acrylic monomer in the polmerizable polymer 10 ranges from 8 wt % to 20 wt %. More preferably, the weight amount of the monofunctional acrylic monomer in the polmerizable polymer 10 ranges from 10 wt % to 15 wt %.

In some embodiments, the weight amount of the multifunctional acrylic monomer in the polmerizable polymer 10 ranges from 15 wt % to 25 wt %.

In some embodiments, the monofunctional acrylic monomer is selected from the group consisting of: dicyclopentadiene methacrylate, triethylene glycol ethyl ether methacrylate, alkoxylated lauryl acrylate, isobornyl methacrylate, lauryl methacrylate, stearyl methacrylate, lauryl acrylate, isobornyl acrylate, tridecyl acrylate, caprolactone acrylate, octylphenol acrylate, and alkoxylated acrylate. However, the present disclosure is not limited thereto.

In some embodiments, the multifunctional acrylic monomer is selected from the group consisting of: trimethylolpropane triacrylate, ethoxylated trimethylolpropane triacrylate, ditrimethylolpropane tetraacrylate, pentaerythritol tetraacrylate, dipentaerythritol pentaacrylate, and ethoxylated pentaerythritol tetraacrylate. However, the present disclosure is not limited thereto.

It should be noted that the addition of the multifunctional acrylic monomer can increase the crosslink density of the polymerizable polymer 10 (after solidification). However, the polymerizable polymer 10 (after solidification) is brittle and lacks softness, which is not beneficial for processing. Therefore, the polymerizable polymer 10 of the present disclosure includes the thiol compound. An addition of the thiol compound enables the polymerizable polymer 10 (after solidification) to have a high density, a softness, and a toughness.

When a weight amount of the thiol compound in the polymerizable polymer 10 is lower than 15 wt %, the polymerizable polymer 10 (after solidification) will be slightly hard. On the other hand, when the weight amount of the thiol compound in the polymerizable polymer 10 is higher than 40 wt %, the polymerizable polymer 10 (after solidification) will be slightly soft, which leads to an inconvenience of fabrication. Therefore, the weight amount of the thiol compound in the polymerizable polymer 10 can be 15 wt %, 20 wt %, 25 wt %, 30 wt %, 35 wt %, or 40 wt %.

In addition, the addition of the thiol compound can enhance a compatibility between the quantum dot particles 11 and the polymerizable polymer 10. Accordingly, the quantum dot particles 11 can be completely encapsulated by the polymerizable polymer 10, so as to enhance the barrier effect of the polymerizable polymer 10 against moisture and oxygen.

In order to enhance the compatibility between the quantum dot particles 11 and the polymerizable polymer 10, a weight amount of the thiol compound is 15 times to 50 times to a weight amount of the plurality of the quantum dot particles. Specifically, the weight amount of the thiol compound can be 15 times, 20 times, 25 times, 30 times, 35 times, 40 times, 45 times, or 50 times to the weight amount of the quantum dot particles 11.

In the present disclosure, the thiol compound can be a primary mercaptan, a secondary mercaptan, or a combination thereof When the thiol compound contains the primary mercaptan and the secondary mercaptan, a weight ratio of the primary mercaptan to the secondary mercaptan ranges from 1:3 to 3:1.

For example, the primary mercaptan can be selected from the group consisting of: 2, 2′-(ethylenedioxy)diethyl mercaptan, 2, 2′-thiodiethyl mercaptan, trimethylolpropane tris(3-mercaptopropionate), polyethylene glycol dithiol, pentaerythritol tetrakis(3-mercaptopropionate), and ethylene glycol dimercaptoacetate. The secondary mercaptan can be selected from the group consisting of: ethyl 2-mercaptopropionate, pentaerythritol tetrakis(3-mercaptobutyrate), 1, 3, 5-tris(3-mercapto butyloxyethyl)-1, 3, 5-triazine-2, 4, 6(1H, 3H, 5H)-trione, and 1,4-butanediol bis(3-mercaptobutyric acid) ester. However, the present disclosure is not limited thereto.

In the present disclosure, the photoinitiator can be used to absorb free radicals, cations, or anions that are generated after being excited by light energy (e.g., ultraviolet light), such that a polymerization reaction can be initiated. In some embodiments, the photoinitiator can be selected from the group consisting of: 1-hydroxycyclohexyl phenyl ketone, benzoyl isopropanol, tribromomethyl phenyl sulfone, and diphenyl(2, 4, 6-trimethylbenzoyl)phosphine oxide. However, the present disclosure is not limited thereto.

In the present disclosure, an addition of the allyl monomer can enhance the compatibility between the polymerizable polymer 10 and the quantum dot particles 11, and the viscosity of the quantum dot composite 1 can be prevented from being too high. While a polarity of the quantum dot composite 1 will be increased due to the addition of the thiol compound, the polarity of the quantum dot composite 1 can be decreased by adding the allyl monomer. For example, the allyl monomer is selected from the group consisting of: diallyl terephthalate, diallyl phthalate, diallyl carbonate, diallyl oxalate, and diallyl isophthalate. However, the present disclosure is not limited thereto.

In the present disclosure, the scattering particles can help scatter light, such that the optical film manufactured from the quantum dot composite 1 can generate a uniform light beam. It should be noted that when a weight amount of the scattering particles is lower than 3 wt %, a haze of the quantum dot composite 1 may be insufficient. When the weight amount of the scattering particles is higher than 30 wt %, the dispersity of the quantum dot particles 11 will be negatively influenced.

The scattering particles can be microbeads having a particle size of from 0.5 μm to 20 μm. A material of the microbeads can be selected from the group consisting of: acrylic, silicon dioxide, germanium dioxide, titanium dioxide, zirconium dioxide, aluminum oxide, and polystyrene.

It should be noted that the polymerizable polymer 10 can further include an inhibitor. An addition of the inhibitor can control a duration for the quantum dot composite 1 to solidify, so that an easy operation can be achieved. If the inhibitor is absent from the polymerizable polymer 10, the polymerizable polymer 10 may be solidified before being uniformly mixed with quantum dot particles 11, which can result in a poor quantum dot composite 1. A weight amount of the inhibitor ranges from 0.05 wt % to 2 wt %.

Referring to FIG. 2, an optical film m1 is provided in the present disclosure. The optical film m1 includes a quantum dot layer 1′, a first substrate layer 2, and a second substrate layer 3. In the present embodiment, the optical film m1 includes the quantum dot layer 1′, the first substrate layer 2, and the second substrate layer 3, and the quantum dot layer 1′ is disposed between the first substrate layer 2 and the second substrate layer 3. In other words, the quantum dot layer 1′ has a first surface 1a and a second surface 1b that are opposite to each other. The first substrate layer 2 is connected with the first surface 1a, and the second substrate layer 3 is connected with the second surface 1b.

The quantum dot layer 1′ can be formed by solidification of the above-mentioned quantum dot composite 1. The specific components of the quantum dot composite 1 were mentioned previously, and will not be reiterated herein. Specifically, the quantum dot composite 1 is disposed on the first substrate layer 2, and then the second substrate layer 3 is disposed on the quantum dot composite 1, so as to form a laminate structure. In an exemplary embodiment, a thickness of the quantum dot layer 1′ ranges from 30 μm to 130 μm.

Subsequently, a solidification step is implemented, such that the quantum dot composite 1 in the laminate structure is solidified and formed into the quantum dot layer 1′. The quantum dot composite 1 can be formed into the quantum dot layer 1′ by light solidification or thermal solidification. Moreover, in the solidification step, the laminate structure can be exposed to an ultraviolet light, so as to facilitate the quantum dot composite 1 to solidify and form into the quantum dot layer 1′. Accordingly, the quantum dot layer 1′ includes a polymer 10′ formed from the polymerizable polymer 10 and the quantum dot particles 11 dispersed in the polymer 10′.

Due to a compact structure of the polymer 10′, the quantum dot layer 1′ can have a good barrier effect against moisture and oxygen. Therefore, materials of the first substrate layer 2 and the second substrate layer 3 do not particularly need to be a material that has a good barrier effect against moisture and oxygen. For example, the materials of the first substrate layer 2 and the second substrate layer 3 can be polyester, such as polyethylene terephthalate (PET), polypropylene terephthalate (PPT), polybutylene terephthalate (PBT), polyethylene naphthalate (PEN), polybutylene naphthalate (PBN), polycyclohexanedimethanol terephthalate (PCT), polycarbonate (PC), and polyarylate. In an exemplary embodiment, the polyester is polyethylene terephthalate. A thickness of each of the first substrate layer 2 and the second substrate layer 3 ranges from 20 μm to 125 μm.

In other words, the quantum dot layer 1′ formed by solidification of the quantum dot composite 1 can have a good barrier effect against moisture and oxygen. Therefore, moisture and oxygen barrier layers that are costly are not required in the optical film m1, thereby reducing a total cost of the optical film m1 and its manufacturing difficulty. In addition, a thickness of the optical film m1 can also be decreased. In an exemplary embodiment, the thickness of the optical film m1 ranges from 90 nm to 380 nm.

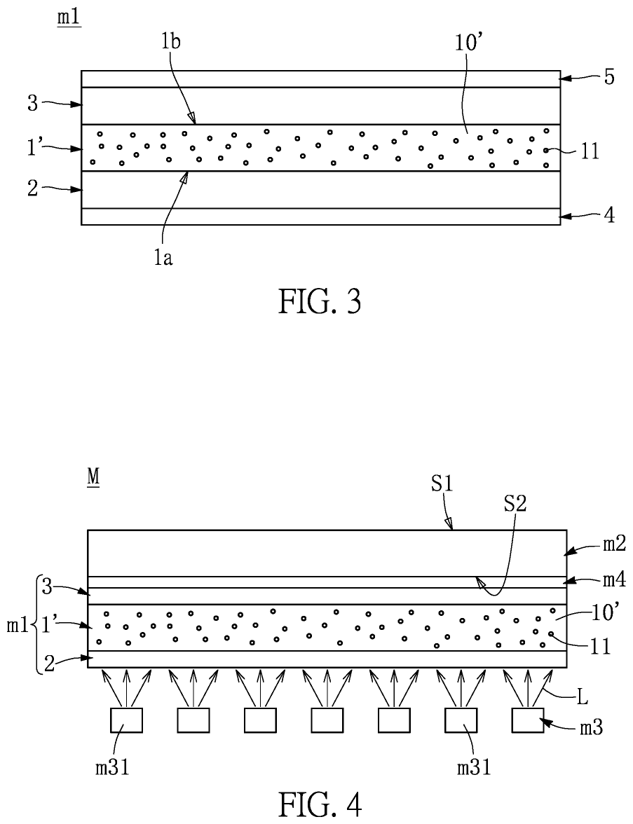

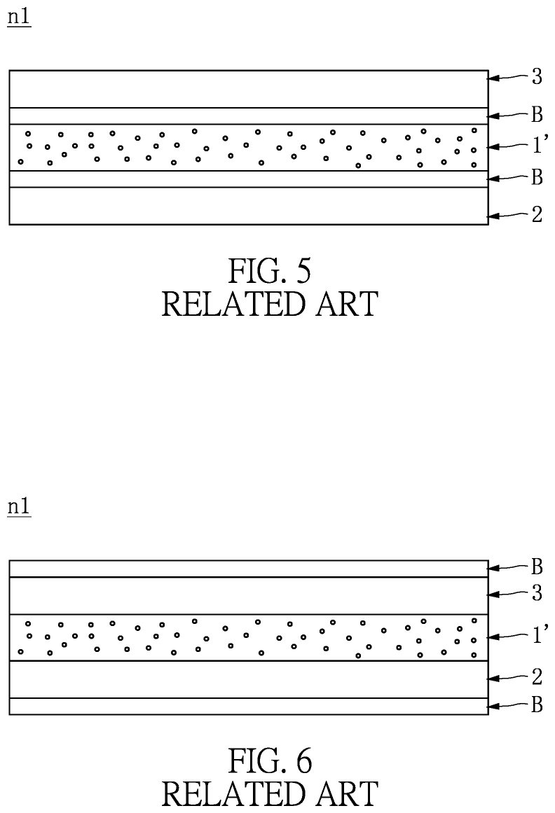

Referring to FIG. 3, another optical film m1 is provided in the present disclosure. The optical film m1 includes a quantum dot layer 1′, a first substrate layer 2, a second substrate layer 3, a first anti-adhesive layer 4, and a second anti-adhesive layer 5. The quantum dot layer 1′ is disposed between the first substrate layer 2 and the second substrate layer 3. The first anti-adhesive layer 4 is formed on the first substrate layer 2. The second anti-adhesive layer 5 is formed on the second substrate layer 3.

The first anti-adhesive layer 4 and the second anti-adhesive layer 5 can prevent the optical film m1 from adhesion during manufacturing or transportation. Materials of the first anti-adhesive layer 4 and the second anti-adhesive layer 5 each include a resin and solid particles. A thickness of each of the first anti-adhesive layer 4 and the second anti-adhesive layer 5 ranges from 3 μm to 10 μm.

Referring to FIG. 4, a backlight module M is provided in the present disclosure. The backlight module M includes the optical film m1, a light guide unit m2, and a light emitting unit m3. The optical film m1 is disposed between the light guide unit m2 and the light emitting unit m3.

In the present embodiment, the optical film m1 is connected with the light guide unit m2 via the second substrate layer 3. Specifically, the optical film m1 can be fixed onto the light guide unit m2 via an optical adhesive layer m4. The materials of the quantum dot layer 1′, the first substrate layer 2, the second substrate layer 3 are mentioned previously, and will not be reiterated herein.

The light guide unit m2 can include at least one of a light guide plate, a reflective plate, a diffusing plate, a prismatic plate, and a polarizing plate. However, the present disclosure is not limited thereto. The light guide unit m2 has a light emitting side S1 and a light entering side S2 that are opposite to each other. The optical film m1 is disposed on the light entering side S2 of the light guide unit m2

The light emitting unit m3 is used to generate a light beam L that is projected toward the light guide unit m2 In the present embodiment, the light emitting unit m3 includes a plurality of light emitting elements m31. The plurality of light emitting elements m31 can be arranged into an array and correspondingly disposed on the light entering side S2 of the light guide unit m2.

In the present embodiment, the optical film m1 can be the optical film m1 as shown in FIG. 2. The optical film m1 includes the quantum dot layer 1′, the first substrate layer 2, and the second substrate layer 3. The quantum dot layer 1′ is disposed between the first substrate layer 2 and the second substrate layer 3. In other words, the quantum dot layer 1′ has the first surface 1a and the second surface 1b that are opposite to each other. In the present embodiment, the optical film m1 is connected with the light guide unit m2 via the second substrate layer 3. Specifically, the optical film m1 can be fixed onto the light entering side S2 of the light guide unit m2 via the optical adhesive layer m4. The materials of the quantum dot layer 1′, the first substrate layer 2, the second substrate layer 3 are mentioned previously, and will not be reiterated herein.

It should be noted that when the light beam L generated by the light emitting unit m3 enters the quantum dot layer 1′, an excitation light beam is generated as a result of the quantum dot particles 11 in the quantum dot layer 1′ being excited by a part of the light beam L. A wavelength of the excitation light beam is different from a wavelength of the light beam L. In other words, a mixed light beam (including the light beam L and the excitation light beam) is generated after the light beam L generated by the light emitting unit m3 passes through the quantum dot layer 1′. Then, the mixed light beam enters the light guide unit m2 through the light entering side S2.

In addition, since the quantum dot layer 1′ of the present disclosure has a good barrier effect against moisture and oxygen, the moisture and oxygen barrier layer that is costly is not required to protect the quantum dot layer 1′. Therefore, the cost of the optical film m1 of the present disclosure can be reduced, and the thickness thereof can also be decreased. When the optical film m1 is applied in the backlight module M of the display, a thickness of the backlight module M can be further decreased.

In order to prove advantages of the quantum dot composite 1, the optical film m1, and the backlight module M of the present disclosure, the quantum dot composites 1 of Examples 1 to 3 and Comparative Examples 1 and 2 are prepared according to the composition listed in Table 1. Each quantum dot composite 1 is used to form the optical film m1 as shown in FIG. 3.

Properties of the optical film m1 are listed in Table 1. After the optical film m1, the light guide unit m2, and the light emitting unit m3 are assembled to form the backlight module M, brightness of the backlight module M and its moisture and oxygen resistant reliability are measured. Test results are listed in Table 1.

The properties listed in Table 1 are measured according to methods below.

Adherence Test: the optical film (the quantum dot layer disposed between the first substrate layer and the second substrate layer) is pulled away by a tensile testing machine.

Shrinkage Rate Test: the optical film is baked in an oven of 85° C. for half an hour, and then a warpage of the optical film is evaluated. The evaluation of “YES” represents that the warpage of the optical film is larger than or equal to 0.2 cm. The evaluation of “NO” represents that the warpage of the optical film is smaller than 0.2 cm.

Brightness Test: a brightness of the mixed light beam generated by the backlight module by using a blue light source (power: 12W; color coordinate: x=0.155, y=0.026; wavelength: 450 nm; FWHM: 20 nm) is measured by a spectrophotometer (model: SR-3AR).

Moisture and Oxygen Resistant Reliability Test: the backlight module is placed in a chamber having a temperature of 65° C. and a relative humidity of 95%. The backlight module is exposed to a blue light with an intensity of 1000 cd/m², and a duration for the mixed light beam to decay by 10% is recorded.

TABLE 1

| | | Example | | | Comparative Example | |
|---|---|---|---|---|---|---|
| | | 1 | 2 | 3 | 1 | 2 |
| Quantum | Monofunctional acrylic monomer | 10.9% | 10.9% | 10.9% | 30% | 5% |
| dot | Multifunctional acrylic monomer | 20% | 40% | 20% | 30% | 40% |
| composite | Thiol compound | 35% | 25% | 40% | 10% | 10.9% |
| | Photoinitiator | 3% | 3% | 3% | 3% | 3% |
| | Allyl monomer | 15% | 5% | 10% | 10.9% | 25% |
| | Scattering particles | 15% | 15% | 15% | 15% | 15% |
| | Quantum dot particles | 1% | 1% | 1% | 1% | 1% |
| | Inhibitor | 0.1% | 0.1% | 0.1% | 0.1% | 0.1% |
| Optical | Thickness (μm) | 300 | 300 | 300 | 300 | 300 |
| film | Thansmittance (%) | 75 | 75 | 75 | 75 | 75 |
| | Refractivity | 1.57 | 1.55 | 1.54 | 1.49 | 1.47 |
| | Adherence | Not separate | Not separate | Separate | Not separate | Not separate |
| | Shrinkage | NO | YES | NO | YES | YES |
| Backlight | Brightness (Cd/m²) | 5000 | 4850 | 4900 | 3600 | 3500 |
| module | Moisture and oxygen resistant | 1500 | 950 | 700 | 500 | 400 |
| | reliability (hour) | | | | | |

According to the results in Table 1, the quantum dot particles can be completely encapsulated by the polymerizable polymer through controlling the composition of the quantum dot composite, so as to possess a good barrier effect against moisture and oxygen. Even in a high temperature and high humidity environment (65° C. and 95% RH), the backlight module formed from the quantum dot composite of the present disclosure can still have a good barrier effect against moisture and oxygen.

With respect to physical properties, the optical films of Examples 1 and 2 have good adherence. When the optical film is tested by the tensile testing machine, the quantum dot layer, the first substrate layer, and the second substrate layer are unable to be separated from one another until the optical film is ruptured. In other words, when the polymerizable polymer contains 15 wt % to 25 wt % of the allyl monomer, the optical film can have good adherence.

In addition, the optical films of Examples 1 and 3 have an acceptable shrinkage rate. Even in the high temperature and high humidity environment, a shape of the optical film can be maintained. Therefore, when the polymerizable polymer contains 15 wt % to 40 wt % of the thiol compound, the optical film can have the acceptable shrinkage rate and the warpage does not occur.

### Beneficial Effects of the Embodiments

In conclusion, in the quantum dot composite, the optical film, and the backlight module provided by the present disclosure, by virtue of “5 wt % to 30 wt % of a monofunctional acrylic monomer”, “10 wt % to 40 wt % of a multifunctional acrylic monomer”, “15 wt % to 40 wt % of a thiol compound”, “1 wt % to 5 wt % of a photoinitiator”, “5 wt % to 25 wt % of an allyl monomer”, and “3 wt % to 30 wt % of scattering particles”, barrier effects of the quantum dot composite, the optical film, and the backlight module against moisture and oxygen can be enhanced.

Further, by virtue of “a weight amount of the thiol compound being 15 times to 50 times of a weight amount of the plurality of the quantum dot particles,” the quantum dot particles can be completely encapsulated by the polymerizable polymer, thereby enhancing the barrier effects of the quantum dot composite, the optical film, and the backlight module against moisture and oxygen.

Further, by virtue of “the allyl monomer being selected from the group consisting of: diallyl terephthalate, diallyl phthalate, diallyl carbonate, diallyl oxalate, and diallyl isophthalate,” the compatibility between the polymerizable polymer and the quantum dot particles can be enhanced, and the quantum dot composite can be prevented from having a high viscosity or a high polarity.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A quantum dot composite, comprising a polymerizable polymer and a plurality of quantum dot particles dispersed in the polymerizable polymer; wherein, based on a total weight of the polymerizable polymer being 100 wt %, the polymerizable polymer includes:
5 wt % to 30 wt % of a monofunctional acrylic monomer,
10 wt % to 40 wt % of a multifunctional acrylic monomer,
15 wt % to 40 wt % of a thiol compound,
1 wt % to 5 wt % of a photoinitiator,
5 wt % to 25 wt % of an allyl monomer, and
3 wt % to 30 wt % of scattering particles.

2. The quantum dot composite according to claim 1, wherein a concentration of the quantum dot particles in the quantum dot composite ranges from 0.1 wt % to 5 wt %.

3. The quantum dot composite according to claim 1, wherein a weight amount of the thiol compound is 15 times to 50 times a weight amount of the quantum dot particles.

4. The quantum dot composite according to claim 1, wherein a ligand is formed on surfaces of the quantum dot particles, and the ligand is selected from the group consisting of: oleic acid, alkyl phosphine, alkyl phosphine oxide, alkyl amines, alkyl carboxylic acid, alkyl mercaptan, and alkyl phosphonic acid.

5. The quantum dot composite according to claim 1, wherein the thiol compound is selected from the group consisting of: 2, 2′-(ethylenedioxy)diethyl mercaptan, 2, 2′-thiodiethyl mercaptan, trimethylolpropane tris(3-mercaptopropionate), polyethylene glycol dithiol, pentaerythritol tetrakis(3-mercaptopropionate), ethylene glycol dimercaptoacetate, ethyl 2-mercaptopropionate, pentaerythritol tetrakis(3-mercaptobutyrate), 1, 3, 5-tris(3-mercapto butyloxyethyl)-1, 3, 5-triazine-2, 4, 6(1H, 3H, 5H)-trione, and 1,4-butanediol bis(3-mercaptobutyric acid) ester.

6. The quantum dot composite according to claim 1, wherein the thiol compound includes a primary mercaptan and a secondary mercaptan, and a weight ratio of the primary mercaptan to the secondary mercaptan ranges from 1:3 to 3:1.

7. The quantum dot composite according to claim 1, wherein the monofunctional acrylic monomer is selected from the group consisting of:
dicyclopentadiene methacrylate, triethylene glycol ethyl ether methacrylate, alkoxylated lauryl acrylate, isobornyl methacrylate, lauryl methacrylate, stearyl methacrylate, lauryl acrylate, isobornyl acrylate, tridecyl acrylate, caprolactone acrylate, octylphenol acrylate, and alkoxylated acrylate.

8. The quantum dot composite according to claim 1, wherein the multifunctional acrylic monomer is selected from the group consisting of:
trimethylolpropane triacrylate, ethoxylated trimethylolpropane triacrylate, ditrimethylolpropane tetraacrylate, pentaerythritol tetraacrylate, dipentaerythritol pentaacrylate, and ethoxylated pentaerythritol tetraacrylate.

9. The quantum dot composite according to claim 1, wherein the allyl monomer is selected from the group consisting of: diallyl terephthalate, diallyl phthalate, diallyl carbonate, diallyl oxalate, and diallyl isophthalate.

10. An optical film, comprising: a quantum dot layer, a first substrate layer, and a second substrate layer; wherein the quantum dot layer is disposed between the first substrate layer and the second substrate layer, the quantum dot layer is formed by solidification of a quantum dot composite, and the quantum dot composite includes a polymerizable polymer and a plurality of quantum dot particles dispersed in the polymerizable polymer;
wherein, based on a total weight of the polymerizable polymer being 100 wt %, the polymerizable polymer includes:
5 wt % to 30 wt % of a monofunctional acrylic monomer,
10 wt % to 40 wt % of a multifunctional acrylic monomer,
15 wt % to 40 wt % of a thiol compound,
1 wt % to 5 wt % of a photoinitiator,
5 wt % to 25 wt % of an allyl monomer, and
3 wt % to 30 wt % of scattering particles.

11. The optical film according to claim 10, wherein materials of the first substrate layer and the second substrate layer are polyethylene terephthalate, and a thickness of each of the first substrate layer and the second substrate layer ranges from 20 μm to 120 μm.

12. The optical film according to claim 10, wherein a thickness of the quantum dot layer ranges from 30 μm to 130 μm.

13. The optical film according to claim 10, wherein the optical film is without a barrier layer.

14. A backlight module, comprising:
a light guide unit having a light entering side and a light emitting side;
at least one light emitting unit generating a light that is projected to the light entering side; and
an optical film disposed on the light entering side of the light guide unit and disposed between the light guide unit and the at least one light emitting unit, wherein the optical film includes:
a quantum dot layer having a first surface and a second surface,
a first substrate layer connected with the first surface of the quantum dot layer, and
a second substrate layer connected with the second surface of the quantum dot layer and the light guide unit;
wherein the quantum dot layer is formed by solidification of a quantum dot composite, and the quantum dot composite includes a polymerizable polymer and a plurality of quantum dot particles dispersed in the polymerizable polymer; wherein, based on a total weight of the polymerizable polymer being 100 wt %, the polymerizable polymer includes:
5 wt % to 30 wt % of a monofunctional acrylic monomer,
10 wt % to 40 wt % of a multifunctional acrylic monomer,
15 wt % to 40 wt % of a thiol compound,
1 wt % to 5 wt % of a photoinitiator,
5 wt % to 25 wt % of an allyl monomer, and
3 wt % to 30 wt % of scattering particles.
